(19) United States
(12) Patent Application Publication
(10) Pub. No.: US 2007/0002551 A1
(43) Pub. Date: Jan. 4, 2007

(54) PRINTED CIRCUIT BOARD ASSEMBLY

(75) Inventor: CHIH-CHAN (Clay) GER, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/308,052

(22) Filed: Mar. 4, 2006

(30) Foreign Application Priority Data
Jul. 1, 2005 (CN) 200510035751.8

(51) Int. Cl. H05K 1/11

(52) U.S. Cl. 361/803; 174/261

(57) ABSTRACT

A printed circuit board (PCB) assembly includes a first PCB (100) and a second PCB (200), respectively including first conductor trace lines (102) and second conductor trace lines (108) for providing electronic connections among a plurality of electronic components. The first PCB is disposed above the second PCB, and is parallel with the second PCB. The first PCB is electronically connected to the second PCB via at least one of the first conductor trace lines and the second conductor trace lines. A surface area of the first PCB is smaller than that of the second PCB. The second PCB is used as a primary circuit board for a layout of electronic components. Preferably, complex or high voltage circuits are disposed on the first PCB, and other circuits are disposed on the second PCB.

### FIELD OF THE INVENTION

The invention relates to printed circuit boards, and particularly to printed circuit board that are integrated together.

### DESCRIPTION OF RELATED ART

Printed circuit boards (PCBs) used in electronic products provide connections among electronic components. With the ongoing development of electronics technology, many electronic components are often required to be disposed on a single PCB. Therefore the circuits disposed on the PCB may be very complex. Nowadays, PCBs are mainly categorized as single-sided boards, double-sided boards, and multi-layer boards. Single-sided boards are the most common kind of PCB in mass-produced consumer electronic products. A single-sided board has all the conductors (copper traces) on one side of the board. Therefore the circuit layout disposed on the single-sided board is restricted, because the traces must not cross each other. Thus, single-sided boards are only suitable for simple circuits. With double-sided boards, the traces can travel from one side of the board to the other through vias. Therefore, double-sided boards are suitable for relatively complex circuits. A multi-layer circuit board is equivalent to an integrated combination of a plurality of single-sided boards and/or double-sided boards. In multi-layer boards, the traces can run on different layers, and use plated through holes or vias to jump from one layer to another. Thus multi-layer boards are used for complex circuits, and are applied as motherboards in computers for example.

Even though multi-layer boards enable construction of circuits of greater complexity and density, they are not always used. This is because of the greater cost of manufacture, and the near impossibility of inspecting, modifying, and repairing the inner layers. In addition, in general, the cost of a single-sided board or of a double-sided board without vias is lower than the cost of a double-sided board with vias and lower than the cost of a multi-layer board. Thus on the one hand, single-sided boards and double-sided boards without vias are preferred in order to reduce costs. On the other hand, double-sided boards with vias or multi-layer boards are needed for more complex circuits. Many PCB designers and manufacturers are liable to be faced with an unsatisfactory choice between simple circuits at a lower cost or more powerful, versatile complex circuits at a greater cost.

Therefore, what is needed is to provide a PCB that can be manufactured at a reduced cost but still have reliable complex circuits.

### SUMMARY OF INVENTION

An exemplary embodiment of the present invention provides a printed circuit board (PCB) assembly. The PCB assembly includes a first PCB and a second PCB, respectively having first conductor trace lines and second conductor trace lines for providing electronic connections among a plurality of electronic components. The first PCB is disposed above the second PCB, and is parallel with the second PCB. The first PCB is electronically connected to the second PCB via at least one of the first conductor trace lines and at least one of the second conductor trace lines. A surface area of the first PCB is smaller than that of the second PCB.

In various embodiments of the present invention, the first PCB is a double-sided or multi-layer board, and the second PCB is a single-sided or double-sided board. The second PCB is used as a primary circuit board for a layout of electronic components. Preferably, complex or high voltage circuits are disposed on the first PCB, and other circuits are disposed on the second PCB. Surface areas of the first PCB and the second PCB can be varied according to circuit design requirements. Compared with conventional multi-layer boards, the PCB assembly can be manufactured at reduced cost while providing complex, reliable circuit layouts.

In addition, an electromagnetic shield can be disposed on the second PCB directly under the first PCB, for shielding the first PCB from electromagnetic interference.

In typical embodiments, the second PCB is a single-sided board that serves as the primary circuit board with a larger surface area. The second PCB is connected to the first PCB, which is a double-sided or multi-layer board with a smaller surface area, to thereby form the PCB assembly. Therefore the PCB assembly can attain complex circuit layouts, greater reliability, and lower production costs. Moreover, the multi-layer board, if used, is relatively thin. Hence, capacitors with either high capacitance or low capacitance can be formed and embedded in the PCB assembly.

Other advantages and novel features will become more apparent from the following detailed description of preferred embodiments when taken in conjunction with the accompanying drawings, in which:

### BRIEF DESCRIPTION OF DRAWINGS

FIG. 1 is a schematic, side cross-sectional view of a PCB assembly of a first exemplary embodiment of the present invention;

FIG. 2 is a schematic, side cross-sectional view of a PCB assembly of a second exemplary embodiment of the present invention;

FIG. 3 is a schematic, side cross-sectional view of a PCB assembly of a third exemplary embodiment of the present invention;

FIG. 4 is a schematic, side cross-sectional view of a PCB assembly of a fourth exemplary embodiment of the present invention;

FIG. 5 is schematic, side cross-sectional view of a PCB assembly of a fifth exemplary embodiment of the present invention; and

FIG. 6 is schematic, side cross-sectional view of a PCB assembly of a sixth exemplary embodiment of the present invention.

### DETAILED DESCRIPTION

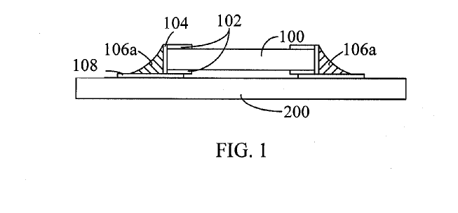

FIG. 1 is a schematic, side cross-sectional view of a printed circuit board (PCB) assembly of a first exemplary embodiment of the present invention. The PCB assembly comprises a first PCB 100 and a second PCB 200. The first PCB 100 is disposed above the second PCB 200, parallel with the second PCB 200. In the exemplary embodiment, the first PCB 100 is a double-sided board, and the second PCB 200 is a single-sided board. In addition, a surface area of the first PCB 100 is smaller than that of the second PCB 200. Further, surface areas of the first PCB 100 and the second PCB 200 can be varied according to circuit design requirements. The second PCB 200 is typically used as a primary circuit board for a layout of electronic components.

The first PCB 100 comprises first conductor trace lines 102 disposed on a top surface and a bottom surface thereof, for providing electronic connections among a plurality of electronic components. The first conductor trace lines 102 are typically etched copper foils. In the exemplary embodiment, a plurality of vias (not shown) are embedded in the first PCB 100. Metal layers (not shown) are formed on inner walls of the vias, for electronically connecting the first conductor trace lines 102 disposed on the top surface of the first PCB 100 to the first conductor trace lines 102 disposed on the bottom surface of the first PCB 100.

The second PCB 200 comprises second conductor trace lines 108 disposed on a top surface thereof. In the exemplary embodiment, the second PCB 200 is electronically connected to the first PCB 100 via the first conductor trace lines 102 disposed on the bottom surface of the first PCB 100 and the second conductor trace lines 108 disposed on the top surface of the second PCB 200. The PCB assembly further comprises a plurality of solder portions 106a to electronically connect the first conductor trace lines 102 of the first PCB 100 and the second conductor trace lines 108 of the second PCB 200. In the exemplary embodiment, the first PCB 100 further comprises a plurality of metal layers 104 for connecting the first conductor trace lines 102 disposed on the top surface of the first PCB 100 to the first conductor trace lines 102 disposed on the bottom surface of the first PCB 100, and for providing joint points for the corresponding solder portions 106a. Each metal layer 104 is typically a thin metal film directly plated on the first PCB 100. Thus, both the metal layers 104 and the metal layers formed on the inner walls of the vias electronically connect the first conductor trace lines 102 disposed on the top surface of the first PCB 100 and the first conductor trace lines 102 disposed on the bottom surface of the first PCB 100.

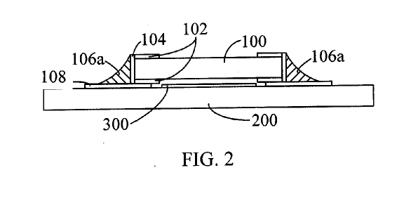

FIG. 2 is a schematic, side cross-sectional view of a PCB assembly of a second exemplary embodiment of the present invention. First conductor trace lines 102 of a first PCB 100 and second conductor trace lines 108 of a second PCB 200 in FIG. 2 have similar connections to those of FIG. 1. The difference is that the second PCB 200 further comprises an electromagnetic shield 300 disposed thereof. That is, the electromagnetic shield 300 is located directly under the first PCB 100, for protecting the first PCB 100 from electromagnetic interference. In this embodiment, the electromagnetic shield 300 is a copper foil.

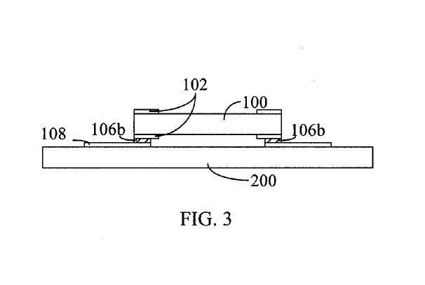

FIG. 3 is a schematic, side cross-sectional view of a PCB assembly of a third exemplary embodiment of the present invention. First conductor trace lines 102 of a first PCB 100 and second conductor trace lines 108 of a second PCB 200 in FIG. 3 have similar connections to those of FIG. 1. However, in this embodiment, some of the first conductor trace lines 102 of the first PCB 100 are electronically connected to the second conductor trace lines 108 of the second PCB 200 via solder portions 106b. In particular, the solder portions 106b are provided between first conductor trace lines 102 disposed on a bottom surface of the first PCB 100 and the second conductor trace lines 108 disposed on a top surface of the second PCB 200.

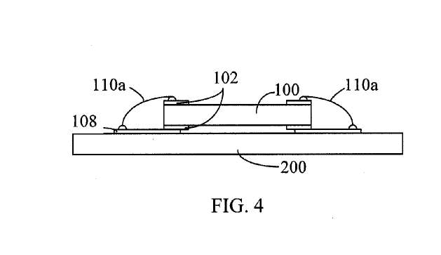

FIG. 4 is a schematic, side cross-sectional view of a PCB assembly of a fourth exemplary embodiment of the present invention. First conductor trace lines 102 of a first PCB 100 and second conductor trace lines 108 of a second PCB 200 in FIG. 4 have similar connections to those of FIG. 1. However, in this embodiment, some of the first conductor trace lines 102 of the first PCB 100 are electronically connected to the second conductor trace lines 108 of the second PCB 200 by a wire soldering process. In particular, solder wires 110a connect first conductor trace lines 102 disposed on a top surface of the first PCB 100 to the second conductor trace lines 108 disposed on a top surface of the second PCB 200.

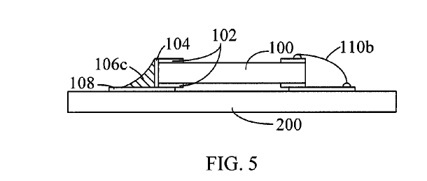

FIG. 5 is a schematic, side cross-sectional view of a PCB assembly of a fifth exemplary embodiment of the present invention. First conductor trace lines 102 of a first PCB 100 and second conductor trace lines 108 of a second PCB 200 in FIG. 5 have similar connections to those of FIG. 1. However, in this embodiment, at least one of the first conductor trace lines 102 of the first PCB 100 is electronically connected to at least one respective second conductor trace line 108 of the second PCB 200 by at least one solder portion 106c. At least another of the first conductor trace lines 102 of the first PCB 100 is electronically connected to at least another respective second conductor trace line 108 of the second PCB 200 by at least one solder wire 1110b. In particular, the solder portion 106c and the solder wire 110b connect respective first conductor trace lines 102 disposed on a top surface of the first PCB 100 to corresponding second conductor trace lines 108 disposed on a top surface of the second PCB 200.

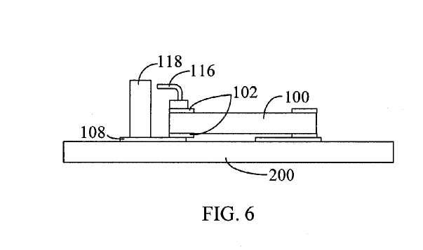

FIG. 6 is a schematic, side cross-sectional view of a PCB assembly of a sixth exemplary embodiment of the present invention. First conductor trace lines 102 of a first PCB 100 and second conductor trace lines 108 of a second PCB 200 in FIG. 5 have similar connections to those of FIG. 1. However, in this embodiment, at least one of the first conductor trace lines 102 of the first PCB 100 is electronically connected to at least one respective second conductor trace line 108 of the second PCB 200 by at least one connector. In particular, in the illustrated embodiment, the first PCB 100 comprises a first connector 116 connected to one of the first conductor trace lines 102 disposed on a top surface of the first PCB 100. The second PCB 200 comprises a second connector 118 connected to one of the second conductor trace lines 108 disposed on a top surface of the second PCB 200. In this embodiment, the first connector 116 is a male connector, and the second connector 118 is a female connector. Alternatively, the first connector 116 can be a female connector, and the second connector 118 can be a male connector. The first connector 116 is inserted into the second connector 118 in a direction parallel with the first PCB 100, and is thus engaged with the second connector 118. Thereby, the first conductor trace line 102 of the first PCB 100 is electronically connected to the second conductor trace line 108 of the second PCB 200.

In any of the above-described embodiments, preferably, complex or high voltage circuits are disposed on the first PCB 100, and other circuits are disposed on the second PCB 200. The first PCB 100 is typically a more expensive double-sided board with a smaller surface area. The second PCB 200 is typically a less expensive single-sided board that serves as the primary circuit board with a larger surface area. Thus overall, the PCB assembly can provide circuits with great complexity and high reliability at a relatively low cost.

In addition, in various alternative embodiments of any of the above-described first through sixth embodiments, the first PCB 100 can be a multi-layer board and is relatively thin. Hence, capacitors with either high capacitance or low capacitance can be formed and embedded in the PCB assembly.

In various further alternative embodiments of any of the above-described first through sixth embodiments and alternatives thereof, the second PCB 200 can be a double-sided board. Furthermore, means of connecting any of the first conductor trace lines 102 of the first PCB 100 and any of the second conductor trace lines 108 of the second PCB 200 can be any suitable one or combination of the means described above in relation to the first through sixth embodiments and alternatives thereof.

While embodiments and methods of the present invention have been described above, it should be understood that they have been presented by way of example only and not by way of limitation. Thus the breadth and scope of the present invention should not be limited by the above-described exemplary embodiments, but should be defined only in accordance with the following claims and their equivalents.

What is claimed is:

1. A printed circuit board assembly, comprising:
a first printed circuit board comprising first conductor trace lines for providing electronic connections among a plurality of electronic components; and
a second printed circuit board comprising second conductor trace lines for providing electronic connections among a plurality of electronic components;
wherein the first printed circuit board is disposed above the second printed circuit board, and is parallel with and electronically connected to the second printed circuit board via at least one of the first conductor trace lines and at least one of the second conductor trace lines; and a surface area of the first printed circuit board is smaller than that of the second printed circuit board.

2. The printed circuit board assembly as claimed in claim 1, wherein the first conductor trace lines are disposed on at least two surfaces of the first printed circuit board, and the second conductor trace lines are disposed on a surface of the second printed circuit board.

3. The printed circuit board assembly as claimed in claim 1, wherein the second printed circuit board is a single-sided board.

4. The printed circuit board assembly as claimed in claim 1, wherein the second printed circuit board is a double-sided board.

5. The printed circuit board assembly as claimed in claim 1, further comprising a solder wire, which connects at least one of the first conductor trace lines of the first printed circuit board and at least one of the second conductor trace lines of the second printed circuit board.

6. The printed circuit board assembly as claimed in claim 1, further comprising a solder portion, which connects at least one of the first conductor trace lines of the first printed circuit board and at least one of the second conductor trace lines of the second printed circuit board.

7. The printed circuit board assembly as claimed in claim 2, wherein the first printed circuit board further comprises a metal layer, which connects at least one of the first conductor trace lines on a first surface of the first printed circuit board and at least another of the first conductor trace lines on a second surface of the first printed circuit board.

8. The printed circuit board assembly as claimed in claim 7, wherein the metal layer is a metal film directly plated on the first printed circuit board.

9. The printed circuit board assembly as claimed in claim 7, wherein the metal layer is formed on an inner wall of a via of the first printed circuit board.

10. The printed circuit board assembly as claimed in claim 1, wherein the first printed circuit board further comprises a first connector electronically connected to at least one of the first conductor trace lines of the first printed circuit board, and the second printed circuit board further comprises a second connector electronically connected to at least one of the second conductor trace lines of the second printed circuit board, and the second connector is engaged with and electronically connected to the first connector.

11. The printed circuit board assembly as claimed in claim 10, wherein the connection of the first connector and the second connector is parallel with the surface of the first printed circuit board.

12. The printed circuit board assembly as claimed in claim 1, wherein the second printed circuit board further comprises an electromagnetic shield disposed thereon under the first printed circuit board.

13. The printed circuit board assembly as claimed in claim 12, wherein the electromagnetic shield comprises a copper foil.
